(19) United States
(12) Patent Application Publication
(10) Pub. No.: US 2024/0055241 A1
(43) Pub. Date: Feb. 15, 2024

(54) ESC TEMPERATURE CONTROL UNIT AND SUBSTRATE TREATING APPARATUS INCLUDING THE SAME

(71) Applicant: SEMES CO., LTD., Chungcheongnam-do (KR)

(72) Inventor: Byeong Hyeon KONG, Chungcheongnam-do (KR)

(21) Appl. No.: 18/206,089

(22) Filed: Jun. 6, 2023

(30) Foreign Application Priority Data
Aug. 12, 2022 (KR) 10-2022-0101185

(51) Int. Cl. H01J 37/32; G05D 23/19

(52) U.S. Cl. CPC H01J 37/32724; G05D 23/1917; H01J 2237/2007; H01J 2237/24585; H01J 2237/2001; H01J 2237/334

(57) ABSTRACT

There are provided an electrostatic chuck (ESC) temperature control unit capable of independently controlling multi-zones of an electrostatic chuck using an alternating current (AC) heater and a direct current (DC) heater, and a substrate treating apparatus including the same. The substrate treating apparatus includes: a housing; a substrate support unit; a shower head unit; a plasma generating unit; and an ESC temperature control unit, wherein the ESC temperature control unit which controls a temperature of the electrostatic chuck includes: a plurality of first heaters; a plurality of second heaters providing power different from that of the first heaters; and a control module controlling the first heaters and the second heaters, and the control module independently controls the first heaters and the second heaters.

### CROSS-REFERENCE TO RELATED APPLICATION

This application claims priority from Korean Patent Application No. 10-2022-0101185 filed on Aug. 12, 2022 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to an electrostatic chuck (ESC) temperature control unit and a substrate treating apparatus including the same. More specifically, the present disclosure relates to an ESC temperature control unit used in a process of fabricating a semiconductor and a substrate treating apparatus including the same.

### 2. Description of the Related Art

Semiconductor element fabricating processes may be continuously performed within a semiconductor fabricating facility, and may be divided into a pre-process and a post-process. The semiconductor fabricating facility may be installed within a semiconductor fabricating plant defined as a Fab in order to fabricate semiconductor elements.

The pre-process refers to a process of forming circuit patterns on a wafer to complete chips. The pre-process may include a deposition process of forming a thin film on the wafer, a photolithography process of transferring a photoresist onto the thin film using a photomask, an etching process of selectively removing unnecessary portions using a chemical material or a reactive gas in order to form desired circuit patterns on the wafer, an ashing process of removing the photoresist remaining after the etching process, an ion implantation process of implanting ions into portions connected to the circuit patterns to impart characteristics of an electronic element, a cleaning process of removing a contamination source on the wafer, and the like.

The post-process refers to a process of evaluating performance of a product completed through the pre-process. The post-process may include a primary inspection process of inspecting whether or not each chip on the wafer operates to sort good products and bad products, a package process of cutting and separating each chip through dicing, die bonding, wire bonding, molding, marking, etc., to form a shape of a product, a final inspection process of finally inspecting characteristics and reliability of the product through electrical characteristic inspection, burn-in inspection, etc., and the like.

When a substrate (e.g., a wafer) is treated using plasma, a substrate support unit supporting the substrate may be provided with a heating member and a cooling member in order to maintain the substrate at a process temperature.

In addition, the substrate support unit may perform temperature control on individual regions of the substrate using the heating member and the cooling member in order to improve etch rate (ER), critical dimension (CD) distribution, or the like, at the time of treating the substrate.

### SUMMARY

Aspects of the present disclosure provide an electrostatic chuck (ESC) temperature control unit capable of independently controlling multi-zones of an electrostatic chuck using an alternating current (AC) heater and a direct current (DC) heater, and a substrate treating apparatus including the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a substrate treating apparatus includes: a housing; a substrate support unit disposed within the housing and supporting a substrate using an electrostatic chuck; a shower head unit disposed in the housing and supplying a process gas in a direction in which the substrate is positioned; a plasma generating unit exciting the process gas into a plasma state so that the substrate is treated; and an ESC temperature control unit provided in the substrate support unit and controlling a temperature of the electrostatic chuck, wherein the ESC temperature control unit includes: a plurality of first heaters; a plurality of second heaters providing power different from that of the first heaters; and a control module controlling the first heaters and the second heaters, and the control module independently controls the first heaters and the second heaters.

According to another aspect of the present disclosure, a substrate treating apparatus includes: a housing; a substrate support unit disposed within the housing and supporting a substrate using an electrostatic chuck; a shower head unit disposed in the housing and supplying a process gas in a direction in which the substrate is positioned; a plasma generating unit exciting the process gas into a plasma state so that the substrate is treated; and an ESC temperature control unit provided in the substrate support unit and controlling a temperature of the electrostatic chuck, wherein the ESC temperature control unit includes: a plurality of first heaters; a plurality of second heaters providing power different from that of the first heaters; and a control module controlling the first heaters and the second heaters, the control module independently controls the first heaters and the second heaters, the control module controls the first heaters and the second heaters in order of the second heaters and the first heaters, the first heaters are heaters operating using DC, and the second heaters are heaters operating using AC, the first heaters are disposed at a higher level than the second heaters, and the first heaters are provided in some of a plurality of regions of the electrostatic chuck, and the second heaters are provided in each of the plurality of regions.

According to an aspect of the present disclosure, an ESC temperature control unit controlling a temperature of an electrostatic chuck supporting a substrate when the substrate is treated using plasma includes: a plurality of first heaters; a plurality of second heaters providing power different from that of the first heaters; and a control module controlling the first heaters and the second heaters, wherein the control module independently controls the first heaters and the second heaters.

Detailed contents of other exemplary embodiments are described in a detailed description and are illustrated in the drawings.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a first illustrative view schematically illustrating an internal structure of a substrate treating apparatus that treats a substrate using plasma;

FIG. 2 is a second illustrative view schematically illustrating an internal structure of a substrate treating apparatus that treats a substrate using plasma;

FIG. 3 is a first illustrative diagram schematically illustrating an internal configuration of an electrostatic chuck (ESC) temperature control unit provided in an electrostatic chuck;

FIG. 4 is an illustrative view illustrating a structure in which first heaters constituting the ESC temperature control unit are disposed within the electrostatic chuck;

FIG. 5 is an illustrative view illustrating a structure in which second heaters constituting the ESC temperature control unit are disposed within the electrostatic chuck;

FIG. 6 is a second illustrative diagram schematically illustrating an internal configuration of an ESC temperature control unit provided in an electrostatic chuck;

FIG. 7 is a first illustrative view illustrating a structure in which surface temperature measurement modules constituting the ESC temperature control unit are disposed within an electrostatic chuck;

FIG. 8 is a second illustrative view illustrating a structure in which surface temperature measurement modules constituting the ESC temperature control unit are disposed within an electrostatic chuck; and

FIG. 9 is a flowchart schematically illustrating an operating method of the ESC temperature control unit constituting the substrate treating apparatus.

### DETAILED DESCRIPTION OF THE EMBODIMENTS

Hereinafter, exemplary embodiments of the present disclosure will be described in detail with reference to the accompanying drawings. The same components in the drawings will be denoted by the same reference numerals, and an overlapping description thereof will be omitted.

The present disclosure relates to an electrostatic chuck (ESC) temperature control unit capable of independently controlling multi-zones of an electrostatic chuck using an alternating current (AC) heater and a direct current (DC) heater, and a substrate treating apparatus including the same. In the case of a region in which the AC heater is positioned in an electrostatic chuck, it is difficult to independently control the multi-zones due to feedback control of an AC heater temperature sensor. In the present exemplary embodiment, multi-zone independent control may be enabled by utilizing an offset function and a multi-zone control function of a sensor. Hereinafter, the present disclosure will be described in detail with reference to drawings and the like.

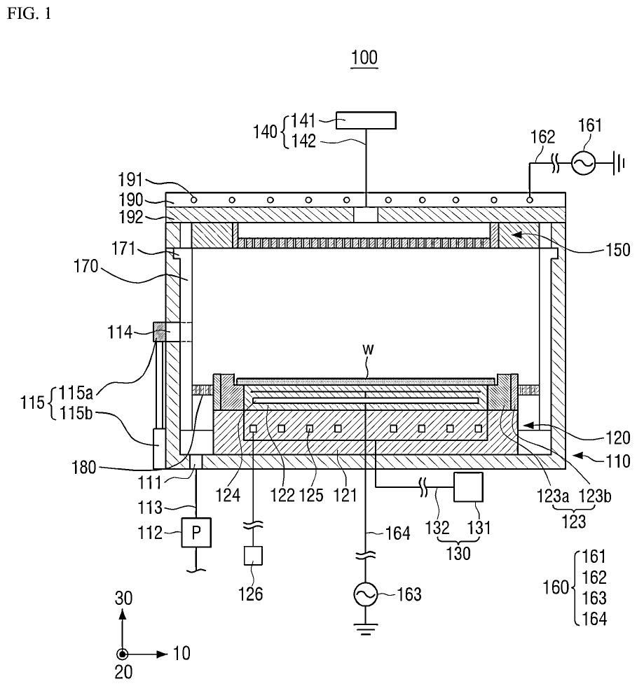

FIG. 1 is a first illustrative view schematically illustrating an internal structure of a substrate treating apparatus that treats a substrate using plasma.

As illustrated in FIG. 1, a substrate treating apparatus 100 may include a housing 110, a substrate support unit 120, a cleaning gas supply unit 130, a process gas supply unit 140, a shower head unit 150, a plasma generating unit 160, a liner unit 170, a baffle unit 180, and an antenna unit 190.

The substrate treating apparatus 100 is an apparatus that processes a substrate W (e.g., a wafer) using plasma. Such a substrate treating apparatus 100 may be provided as an etching process chamber to etch the substrate W in a vacuum environment. However, the present exemplary embodiment is not limited thereto. The substrate treating apparatus 100 may also be provided as a deposition process chamber or a cleaning process chamber to deposit the substrate W in a vacuum environment or dry-clean the substrate W.

The housing 110 provides a space in which a process of treating the substrate W using plasma, that is, a plasma process is executed. Such a housing 110 may have an exhaust hole 111 formed at a lower portion thereof.

The exhaust hole 111 may be connected to an exhaust line 113 mounted with a pump 112. The exhaust hole 111 may exhaust reaction by-products generated during the plasma process and a gas remaining inside the housing 110 to the outside of the housing 110 through the exhaust line 113. In this case, an internal space of the housing 110 may be decompressed to a predetermined pressure.

The housing 110 may have an opening 114 formed in a sidewall thereof. The opening 114 may function as a passage through which the substrate W enters and exits the housing 110. The opening 114 may be configured to be automatically opened and closed by, for example, a door assembly 115.

The door assembly 115 may include an outer door 115a and a door actuator 115b. The outer door 115a is provided on an outer wall of the housing 110. Such an outer door 115a may be moved in a height direction of the substrate treating apparatus 100, that is, in a third direction 30 through the door actuator 115b. The door actuator 115b may operate using any one selected among a motor, a hydraulic cylinder, and a pneumatic cylinder.

The substrate support unit 120 is installed in a lower region inside the housing 110. Such a substrate support unit 120 may support the substrate W using an electrostatic force. However, the present exemplary embodiment is not limited thereto. The substrate support unit 120 may support the substrate W using various methods such as mechanical clamping and vacuum.

When the substrate support unit 120 supports the substrate W using the electrostatic force, the substrate support unit 120 may include a base 121 and an electrostatic chuck (ESC) 122.

The electrostatic chuck 122 is a substrate support member supporting the substrate W seated thereon using the electrostatic force. Such an electrostatic chuck 122 may be disposed on the base 121 and be made of ceramic.

A ring assembly 123 is provided to surround an outer edge region of the electrostatic chuck 122. Such a ring assembly 123 may include a focus ring 123a and an edge ring 123b.

The focus ring 123a may be formed inside the edge ring 123b, and may be provided to surround an outer region of the electrostatic chuck 122. The focus ring 123a may serve to concentrate ions on the substrate W when the plasma process is performed inside the housing 110, and may be made of silicon.

The edge ring 123b may be formed outside the focus ring 123a, and may be provided to surround an outer region of the focus ring 123a. The edge ring 123b may serve to prevent side surfaces of the electrostatic chuck 122 from being damaged by the plasma, and may be made of an insulator material, for example, quartz.

A heating member 124 and the cooling member 125 are provided in order to maintain the substrate W at a process temperature when a substrate treating process is performed inside the housing 110. The heating member 124 may be provided as a heater wire or the like in order to raise a temperature of the substrate W, and may be installed inside the electrostatic chuck 122, for example. The cooling member 125 may be provided as a cooling line through which a refrigerant flows in order to lower a temperature of the substrate W, and may be installed inside the base 121, for example.

Meanwhile, the cooling member 125 may receive the refrigerant using a chiller 126. The chiller 126 may be separately installed outside the housing 110.

The cleaning gas supply unit 130 supplies a cleaning gas in order to remove foreign materials remaining on the electrostatic chuck 122 or the ring assembly 123. The cleaning gas supply unit 130 may provide, for example, a nitrogen gas (N₂ gas) as the cleaning gas, and may include a cleaning gas supply source 131 and a cleaning gas supply line 132.

The cleaning gas supply line 132 transfers the cleaning gas supplied by the cleaning gas supply source 131. Such a cleaning gas supply line 132 may be connected to a space between the electrostatic chuck 122 and the focus ring 123a, and the cleaning gas may move through the space to remove foreign materials remaining at an edge portion of the electrostatic chuck 122, an upper portion of the ring assembly 123, or the like.

The process gas supply unit 140 supplies a process gas to the internal space of the housing 110. Such a process gas supply unit 140 may supply the process gas through a hole formed to penetrate through an upper cover of the housing 110 or supply the process gas through a hole formed to penetrate through a sidewall of the housing 110. The process gas supply unit 140 may include a process gas supply source 141 and a process gas supply line 142.

The process gas supply source 141 may provide a gas used to treat the substrate W as the process gas, and at least one process gate supply source 141 may be provided within the substrate treating apparatus 100. When a plurality of process gas supply sources 141 are provided within the substrate treating apparatus 100, the plurality of process gas supply sources 141 may supply the same type of process gas to obtain an effect of providing a large amount of gas within a short time, and may also supply different types of process gases.

The process gas supply line 142 transfers the process gas provided by the process gas supply source 141 to the shower head unit 150. To this end, the process gas supply line 142 may be provided to connect the process gas supply source 141 and the shower head unit 150 to each other.

Meanwhile, although not illustrated in FIG. 1, the process gas supply unit 140 may further include a process gas distributor and a process gas distribution line for distributing the process gas to each module of the shower head unit 150 when the shower head unit 150 is divided into a plurality of modules. The process gas distributor may be installed on the process gas supply line 142 and may distribute the process gas supplied from the process gas supply source 141 to each module of the shower head unit 150. The process gas distribution line may be configured to connect the process gas distributor and each module of the shower head unit 150 to each other, and may transfer the process gas distributed by the process gas distributor to each module of the shower head unit 150.

The shower head unit 150 may be disposed in the internal space of the housing 110, and may include a plurality of gas feeding holes. Here, the plurality of gas feeding holes may be formed to penetrate through a surface of a body of the shower head unit 150 and may be formed on the body at regular intervals. Such a shower head unit 150 may uniformly feed the process gas supplied through the process gas supply unit 140 onto the substrate W within the housing 110.

The shower head unit 150 may be installed to face the electrostatic chuck 122 in a vertical direction (third direction 30) within the housing 110. In this case, the shower head unit 150 may be provided to have a greater diameter than the electrostatic chuck 122 or may be provided to have the same diameter as the electrostatic chuck 122. The shower head unit 150 may be made of silicon or a metal.

Although not illustrated in FIG. 1, the shower head unit 150 may be divided into the plurality of modules. For example, the shower head unit 150 may be divided into three modules such as a first module, a second module, and a third module. The first module may be disposed at a position corresponding to a center region of the substrate W. The second module may be disposed to surround an outer side of the first module, and may be disposed at a position corresponding to a middle region of the substrate W. The third module may be disposed to surround an outer side of the second module, and may be disposed at a position corresponding to an edge region of the substrate W.

The plasma generating unit 160 generates plasma from a gas remaining in a discharge space. Here, the discharge space refers to a space positioned above the substrate W in the internal space of the housing 110.

The plasma generating unit 160 may generate the plasma in the discharge space inside the housing 110 using an inductively coupled plasma (ICP) source. The plasma generating unit 160 may generate the plasma in the discharge space inside the housing 110 by using, for example, the antenna unit 190 as a first electrode and the electrostatic chuck 122 as a second electrode.

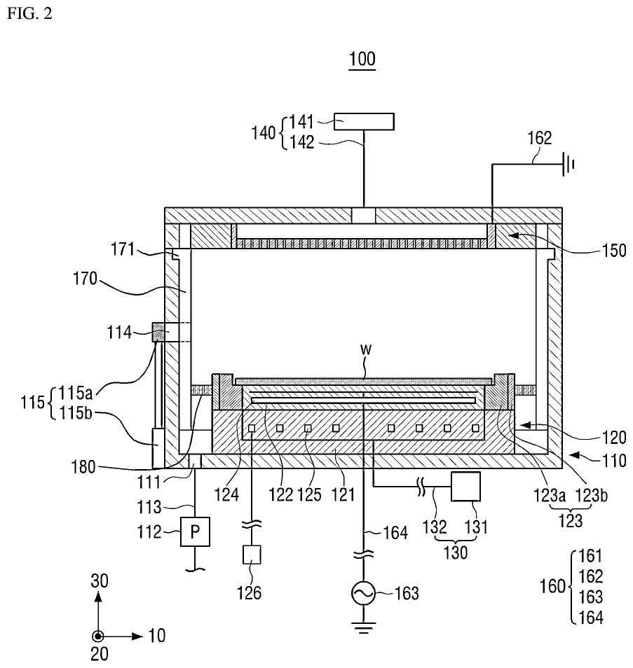

However, the present exemplary embodiment is not limited thereto. The plasma generating unit 160 may generate the plasma in the discharge space inside the housing 110 using a capacitively coupled plasma (CCP) source The plasma generating unit 160 may generate the plasma in the discharge space inside the housing 110 by using, for example, the shower head unit 150 as a first electrode and the electrostatic chuck 122 as a second electrode. FIG. 2 is a second illustrative view schematically illustrating an internal structure of a substrate treating apparatus that treats a substrate using plasma.

A description will be provided with reference to FIG. 1 again.

The plasma generating unit 160 may include a first high frequency power source 161, a first transmission line 162, a second high frequency power source 163, and a second transmission line 164.

The first high frequency power source 161 applies radio frequency (RF) power to the first electrode. Such a first high frequency power source 161 may serve to control characteristics of the plasma within the substrate treating apparatus 100. For example, the first high frequency power source 161 may serve to adjust ion bombardment energy within the substrate treating apparatus 100.

A single first high frequency power source 161 may be provided within the substrate treating apparatus 100, but a plurality of first high frequency power sources 161 may be provided within the substrate treating apparatus 100. When the plurality of first high frequency power sources 161 are provided within the substrate treating apparatus 100, they may be disposed in parallel on the first transmission line 162.

When the plurality of first high frequency power sources 161 are provided within the substrate treating apparatus 100, although not illustrated in FIG. 1, the plasma generating unit 160 may further include a first matching network electrically connected to the plurality of first high frequency power sources. Here, the first matching network may serve to match frequency power of different magnitudes and apply the frequency power to the first electrode when the frequency power of the different magnitudes is input from the respective first high frequency power sources.

The first transmission line 162 connects the first electrode and a ground to each other. The first high frequency power source 161 may be installed on the first transmission line 162.

Meanwhile, although not illustrated in FIG. 1, a first impedance matching circuit may be provided on the first transmission line 162 connecting the first high frequency power source 161 and the first electrode to each other for the purpose of impedance matching. The first impedance matching circuit may act as a lossless passive circuit to allow maximum electrical energy to be transferred from the first high frequency power source 161 to the first electrode.

The second high frequency power source 163 applies RF power to the second electrode. Such a second high frequency power source 163 may serve as a plasma source generating the plasma within the substrate treating apparatus 100 or may serve to control characteristics of the plasma together with the first high frequency power source 161.

A single second high frequency power source 163 may be provided within the substrate treating apparatus 100, but a plurality of second high frequency power sources 163 may be provided within the substrate treating apparatus 100. When the plurality of second high frequency power sources 163 are provided within the substrate treating apparatus 100, they may be disposed in parallel on the second transmission line 164.

When the plurality of second high frequency power sources 163 are provided within the substrate treating apparatus 100, although not illustrated in FIG. 1, the plasma generating unit 160 may further include a second matching network electrically connected to the plurality of second high frequency power sources. Here, the second matching network may serve to match frequency power of different magnitudes and apply the frequency power to the second electrode when the frequency power of the different magnitudes is input from the respective second high frequency power sources.

The second transmission line 164 connects the second electrode and a ground to each other. The second high frequency power source 163 may be installed on the second transmission line 164.

Meanwhile, although not illustrated in FIG. 1, a second impedance matching circuit may be provided on the second transmission line 164 connecting the second high frequency power source 163 and the second electrode to each other for the purpose of impedance matching. The second impedance matching circuit may act as a lossless passive circuit to allow maximum electrical energy to be transferred from the second high frequency power source 163 to the second electrode.

When the second high frequency power source 163 is installed on the second transmission line 164, it is possible for the plasma generating unit 160 to apply a multi-frequency to the substrate treating apparatus 100, and accordingly, substrate treating efficiency of the substrate treating apparatus 100 may be improved. However, the present exemplary embodiment is not limited thereto. The plasma generating unit 160 may also be configured without the second high frequency power source 163. That is, the second high frequency power source 163 may not be installed on the second transmission line 164.

The liner unit (or a wall liner) 170 is provided to protect an inner portion of the housing 110 from arc discharge generated in a process in which the process gas is excited, impurities generated during the substrate treating process, or the like. To this end, the liner unit 170 may be formed to cover an inner sidewall of the housing 110.

The liner unit 170 may include a support ring 171 formed at an upper portion thereof. The support ring 171 may be formed to protrude from the upper portion of the liner unit 170 in an outward direction (i.e., a first direction 10), and may serve to fix the liner unit 170 to the housing 110.

The baffle unit 180 serves to exhaust process by-products of the plasma, unreacted gases, and the like. Such a baffle unit 180 may be installed in a space between the inner sidewall of the housing 110 and the substrate support unit 120, and may be provided in an annular ring shape. The baffle unit 180 may include a plurality of through holes penetrating therethrough in the vertical direction (i.e., the third direction 30) in order to control a flow of the process gas.

The antenna unit 190 serves to excite the process gas into plasma by generating a magnetic field and an electric field inside the housing 110. To this end, the antenna unit 190 may include an antenna 191 provided to form a closed loop using a coil, and may use the RF power supplied from the first high frequency power source 131.

The antenna unit 190 may be installed on an upper surface of the housing 110. In this case, the antenna 191 may be installed with a width direction (first direction 10) of the housing 110 as a length direction, and may be provided to have a size corresponding to a diameter of the housing 110.

The antenna unit 190 may be formed to have a planar type. However, the present exemplary embodiment is not limited thereto. The antenna unit 190 may also be formed to have a cylindrical type. In this case, the antenna unit 190 may be installed to surround the outer sidewall of the housing 110.

Meanwhile, the antenna unit 190 may include a window module 192. The window module 192 may serve as a top cover of the housing 110 sealing the internal space of the housing 110 by covering a top of the housing 110 when the top of the housing 110 is opened.

The window module 192 may be formed as a dielectric window made of an insulating material (e.g., alumina (Al₂O₃)). The window module 192 may include a coating film formed on a surface thereof in order to suppress generation of particles when the plasma process is performed inside the housing 110.

As described above, the purpose of a multi-zone function includes a temperature distribution improvement effect, but also includes the purpose of improving etch rate (ER), critical dimension (CD) distribution, or the like, through individual region temperature control. Accordingly, a temperature is changed by controlling an output of a DC heater in each region of multi-zones, but in a region in which a sensor for controlling an AC heater is positioned, independent control is impossible due to feedback control of the AC heater.

The present disclosure relates to multi-zone independent control utilizing a substrate temperature sensor offset function. In a region in which an AC heater temperature sensor of the substrate is positioned, multi-zone independent control was not possible due to feedback control of the sensor, but in the present disclosure, an algorithm utilizing an sensor offset function and a multi-zone control function was developed to enable the multi-zone independent control.

Hereinafter, a component including an AC heater, a DC heater, a power supply module, a control module, and the like, provided in the electrostatic chuck 122 for multi-zone independent control will be defined as an ESC temperature control unit, and the ESC temperature control unit will be described.

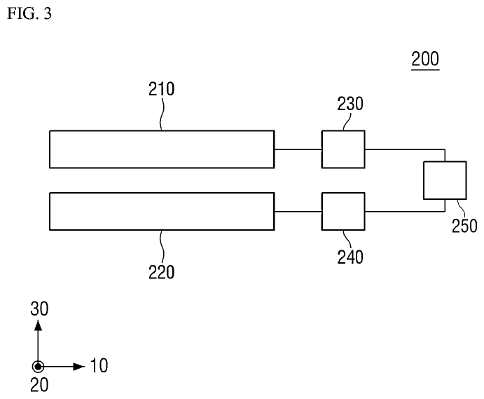

FIG. 3 is a first illustrative diagram schematically illustrating an internal configuration of an electrostatic chuck (ESC) temperature control unit provided in an electrostatic chuck.

As illustrated FIG. 3, an ESC temperature control unit 200 may include a first heater 210, a second heater 220, a first power supply module 230, a second power supply module 240, and a control module 250.

The ESC temperature control unit 200 may be used to evaluate and improve CD distribution of the substrate W when the substrate W is treated using the plasma within the substrate treating apparatus 100. The ESC temperature control unit 200 may be provided in the substrate support unit 120 instead of the heating member 124. Alternatively, the ESC temperature control unit 200 may be provided in the substrate support unit 120 instead of the heating member 124 and the cooling member 125.

The first heater 210 may operate using power provided from the first power supply module 230. The first heater 210 may operate with DC power, and may be provided as, for example, a DC heater.

The first heater 210 may be provided at a higher level than the second heater 220. The number of first heaters 210 may be larger than that of second heaters 220. A plurality of first heaters 210 may be provided within the electrostatic chuck 122.

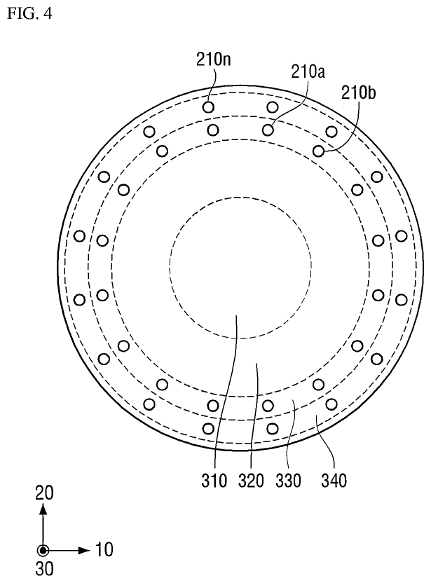

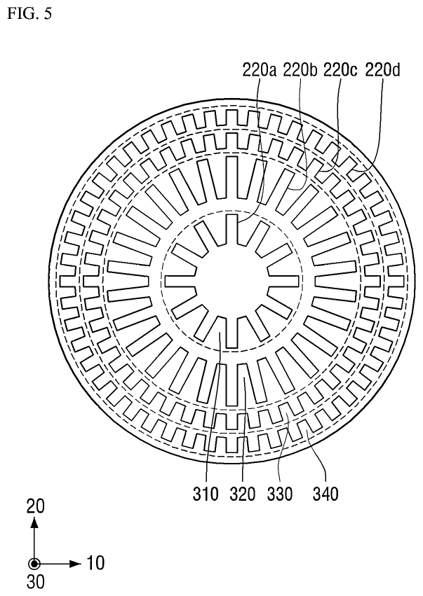

The electrostatic chuck 122 may be divided into a plurality of regions. For example, the electrostatic chuck 122 may be divided into four regions as illustrated in FIGS. 4 and 5. Here, the four regions may be a first region 310, a second region 320, a third region 330 and a fourth region 340.

The first region 310 corresponds to a center region of the electrostatic chuck 122. The second region 320 corresponds to a middle region of the electrostatic chuck 122. The middle region may be a region positioned outside the center region and surrounding the center region. The third region 330 corresponds to an edge region of the electrostatic chuck 122. The edge region may be a region positioned outside the middle region and surrounding the middle region. The fourth region 340 corresponds to an extremely edge region of the electrostatic chuck 122. The extremely edge region may be a region positioned outside the edge region and surrounding the edge region.

Meanwhile, the electrostatic chuck 122 is not limited to being divided into the four regions. For example, the electrostatic chuck 122 may also be divided into three regions. Here, the three regions may be the first region 310 corresponding to the center region of the electrostatic chuck 122, the second region 320 corresponding to the middle region of the electrostatic chuck 122, and the third region 330 corresponding to the edge region of the electrostatic chuck 122.

When the electrostatic chuck 122 is divided into the plurality of regions, the first heaters 210 may not be provided in all regions and may be provided only in some regions. For example, the first heaters 210 may be provided in the third region 330 and the fourth region 340 as illustrated in FIG. 4. FIG. 4 is an illustrative view illustrating a structure in which first heaters constituting the ESC temperature control unit are disposed within the electrostatic chuck.

As described above, the first heaters 210 may be provided as a plurality of first heaters 210a, 210b, . . . , 210n within the electrostatic chuck 122. For example, thirty-two first heaters 210 may be provided within the electrostatic chuck 122.

The plurality of first heaters 210a, 210b, . . . , 210n may be provided in the same number in the third region 330 and the fourth region 340. For example, sixteen first heaters 210a, 210b, . . . , 210n may be provided in the third region 330 and sixteen heaters 210a, 210b, . . . , 210n may be provided in the fourth region 340.

However, the present exemplary embodiment is not limited thereto. The plurality of first heaters 210a, 210b, . . . , 210n may also be provided in different numbers in the third region 330 and the fourth region 340.

The respective first heaters provided in the third region 330 may be disposed at regular intervals in consideration of characteristics of DC heaters. Similarly, the respective first heaters provided in the fourth region 340 may be disposed at regular intervals. Here, an interval between two different first heaters provided in the fourth region 340 may be greater than an interval between two different first heaters provided in the third region 330.

However, the present exemplary embodiment is not limited thereto. In order to make an interval between two different first heaters provided in the third region 330 and an interval between two different first heaters provided in the fourth region 340 equal to each other, a larger number of first heaters 210 may also be disposed in the fourth region 340 than in the third region 330.

Meanwhile, when the electrostatic chuck 122 is divided into the three regions, the plurality of first heaters 210a, 210b, . . . , 210n may also be provided only in the third region 330 in consideration of CD distribution in the edge region of the electrostatic chuck 122.

A description will be provided with reference to FIG. 3 again.

The second heater 220 may operate using power provided from the second power supply module 240. The second heater 220 may operate with AC power, and may be provided as, for example, an AC heater.

The first heater 210 and the second heater 220 may operate with different types of power. As described above, the first heater 210 may operate with the DC power, and the second heater 220 may operate with the AC power. However, the present exemplary embodiment is not limited thereto. The first heater 210 may operate with AC power and the second heater 220 may operate with DC power.

The second heater 220 may be a high-output heater that outputs a large amount of thermal energy. The second heater 220 may be a heater that output a relatively larger amount of thermal energy than the first heater 210. The first heater 210 may be a low-output heater that outputs a smaller amount of thermal energy than the second heater 220.

The second heater 220 may be provided at a lower level than the first heater 210. The number of second heaters 220 may be smaller than that of first heaters 210. A plurality of second heaters 220 may be provided within the electrostatic chuck 122.

As described above, the electrostatic chuck 122 may be divided into the plurality of regions. For example, the electrostatic chuck 122 may be divided into the four regions such as the center region, the middle region, the edge region, and the extremely edge region or may be divided into the three regions such as the center region, the middle region, and the edge region.

When the electrostatic chuck 122 is divided into the plurality of regions, the second heaters 220 may be provided in all regions. For example, the second heaters 220 may be provided in the first region 310, the second region 320, the third region 330, and the fourth region 340, respectively, as illustrated in FIG. 5. FIG. 5 is an illustrative view illustrating a structure in which second heaters constituting the ESC temperature control unit are disposed within the electrostatic chuck.

As described above, the second heaters 220 may be provided as a plurality of second heaters 220a, 220b, 220c, and 220d within the electrostatic chuck 122. For example, four second heaters 220 may be provided within the electrostatic chuck 122.

The plurality of second heaters 220a, 220b, 220c, and 220d may be provided in the same number in the respective regions 310, 320, 330, and 340. For example, one second heaters 220a, 220b, 220c, and 220d may be provided in the respective regions 310, 320, 330, and 340, respectively.

However, the present exemplary embodiment is not limited thereto. The plurality of second heaters 220a, 220b, 220c, and 220d may also be provided in different numbers in the respective regions 310, 320, 330, and 340. Alternatively, the plurality of second heaters 220a, 220b, 220c, and 220d may also be provided in the same number in some regions and be provided in different numbers in some other regions.

The second heaters 220a, 220b, 220c, and 220d provided in the respective regions 310, 320, 330, and 340 may be formed in a heater wire shape. In this case, the second heaters 220a, 220b, 220c, and 220d provided in the respective regions 310, 320, 330, and 340 may be formed according to a zigzag pattern.

Meanwhile, the second heater 220 may perform feedback control. On the other hand, the first heater 210 may not perform feedback control.

The first heaters 210a, 210b, . . . , 210n and the second heaters 220a, 220b, 220c, and 220d may be disposed at different levels within the electrostatic chuck 122, and while the first heaters 210a, 210b, . . . , 210n may be provided in some regions of the electrostatic chuck 122, the second heaters 220a, 220b, 220c, and 220d may be provided in all regions of the electrostatic chuck 122. For example, in the third region 330 and the fourth region 340 of 122 of the electrostatic chuck, the first heaters 210a, 210b, . . . , 210n and the second heaters 220a, 220b, 220c, and 220d may be disposed at upper and lower levels, respectively. In this case, the first heaters 210a, 210b, . . . , 210n and the second heaters 220a, 220b, 220c, and 220d may be distributed so as not to overlap each other in the height direction (third direction 30) of the electrostatic chuck 122.

A description will be provided with reference to FIG. 3 again.

The first power supply module 230 is a module that provides power to the first heater 210. For example, the first power supply module 230 may provide the DC power to each of the first heaters 210a, 210b, . . . , 210n.

The second power supply module 240 is a module that provides power to the second heater 220. For example, the second power supply module 240 may provide the AC power to each of the second heaters 220a, 220b, 220c, and 220d.

The control module 250 is a module that controls operations of the first power supply module 230 and the second power supply module 240. The control module 250 may independently control the first power supply module 230 and the second power supply module 240, and accordingly, the first heater 210 and the second heater 220 may operate at the same time or may operate at different times.

Meanwhile, in the present exemplary embodiment, it is also possible that a control module that controls the first power supply module 230 and a control module that controls the second power supply module 240 are provided separately.

The ESC temperature control unit 200 may further include a surface temperature measurement module in order to control the operations of the first heater 210 and the second heater 220 based on an upper surface temperature of the electrostatic chuck 122.

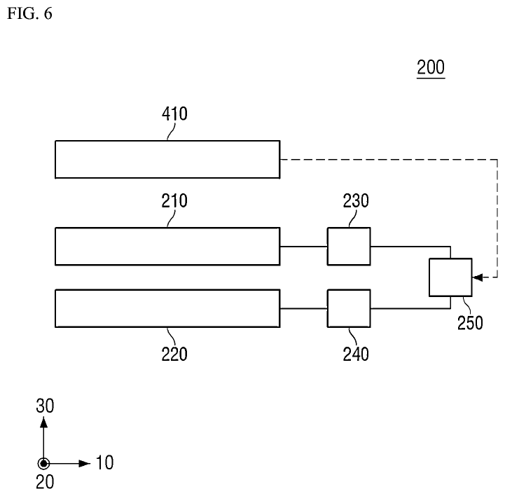

FIG. 6 is a second illustrative diagram schematically illustrating an internal configuration of an ESC temperature control unit provided in an electrostatic chuck.

As illustrated FIG. 6, an ESC temperature control unit 200 may include a first heater 210, a second heater 220, a first power supply module 230, a second power supply module 240, a control module 250, and a surface temperature measurement module 410.

The first heater 210, the second heater 220, the first power supply module 230, the second power supply module 240, and the control module 250 have been described above with reference to FIGS. 3 to 5, and thus, a detailed description thereof will be omitted.

The surface temperature measurement module 410 serves to measure a surface temperature of the electrostatic chuck 122 and provides measured data to the control module 250. The surface temperature measurement module 410 may be disposed at a higher level than the first heater 210 and the second heater 220.

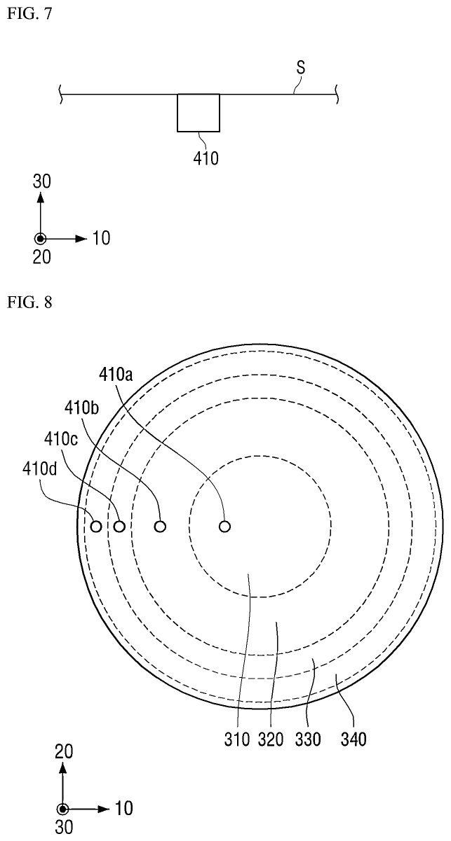

The surface temperature measurement module 410 may be installed to be exposed to, for example, an upper surface of the electrostatic chuck 122 as illustrated in FIG. 7, in order to measure the surface temperature of the electrostatic chuck 122. The surface temperature measurement module 410 may be provided as an optical sensor, and the surface temperature of the electrostatic chuck 110 may be measured through the optical sensor. FIG. 7 is a first illustrative view illustrating a structure in which surface temperature measurement modules constituting the ESC temperature control unit are disposed within an electrostatic chuck.

As described above, the electrostatic chuck 122 may be divided into the plurality of regions. When the electrostatic chuck 122 is formed as described above, the surface temperature measurement module 410 may be provided in each region of the electrostatic chuck 122. For example, when the electrostatic chuck 122 is divided into the four regions such as the center region, the middle region, the edge region, and the extremely edge region, the surface temperature measurement modules 410 may be provided in the first region 310, the second region 320, the third region 330, and the fourth region 340, respectively, as illustrated in FIG. 8. FIG. 8 is a second illustrative view illustrating a structure in which surface temperature measurement modules constituting the ESC temperature control unit are disposed within an electrostatic chuck.

Similarly, when the electrostatic chuck 122 is divided into the three regions such as the center region, the middle region, and the edge region, the surface temperature measurement modules 410 may be provided in the first region 310, the second region 320, and the third region 330, respectively.

The surface temperature measurement modules 410 may be provided as a plurality of surface temperature measurement modules 410a, 410b, 410c, and 410d within the electrostatic chuck 122, similar to the first heaters 210 and the second heaters 220. For example, four surface temperature measurement modules 410 may be provided within the electrostatic chuck 122.

The plurality of surface temperature measurement modules 410a, 410b, 410c, and 410d may be provided in the same number in the respective regions 310, 320, 330, and 340. For example, one surface temperature measurement modules 410a, 410b, 410c, and 410d may be provided in the respective regions 310, 320, 330, and 340, respectively.

However, the present exemplary embodiment is not limited thereto. The plurality of surface temperature measurement modules 410a, 410b, 410c, and 410d may also be provided in different numbers in the respective regions 310, 320, 330, and 340. Alternatively, the plurality of surface temperature measurement modules 410a, 410b, 410c, and 410d may also be provided in the same number in some regions and be provided in different numbers in some other regions.

As described above, one surface temperature measurement modules 410a, 410b, 410c, and 410d may be provided in the respective regions 310, 320, 330, and 340, respectively. In this case, temperatures in the respective regions 310, 320, 330, and 340 may be represented using values of one surface temperature measurement modules 410a, 410b, 410c, and 410d as representative values. However, when there is a temperature difference between portions within a region, it may be inappropriate for a temperature in a specific portion within the region to represent a temperature in the corresponding region.

In the present exemplary embodiment, the plurality of surface temperature measurement modules 410a, 410b, 410c, and 410d may be provided in the plural number in the respective regions 310, 320, 330, and 340 in consideration of such an aspect. In addition, the plurality of surface temperature measurement modules 410a, 410b, 410c, and 410d may be provided in different numbers in the respective regions 310, 320, 330, and 340 so as to be evenly distributed according to a size of each region.

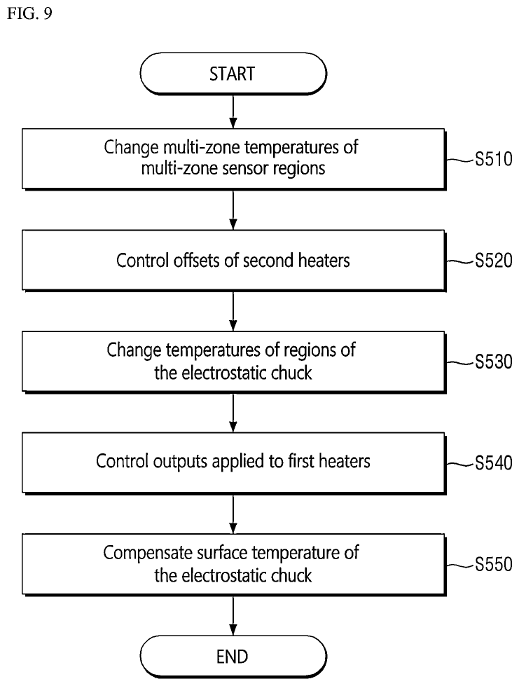

Next, an operating method of the ESC temperature control unit 200 will be described. FIG. 9 is a flowchart schematically illustrating an operating method of the ESC temperature control unit constituting the substrate treating apparatus.

First, the control module 250 performs setting and calibration so that uniform treating of the substrate W is enabled. The control module 250 performs setting and calibration by changing multi-zone temperatures of multi-zone sensor regions, which are the respective regions of the electrostatic chuck 122 (S510).

Then, the second power supply module 240 applies power to the second heaters 220a, 220b, 220c, and 220d in the respective regions. The second heaters 220a, 220b, 220c, and 220d may be AC heaters, and the second power supply module 240 may apply power to the second heaters 220a, 220b, 220c, and 220d in the respective regions according to the control of the control module 250.

In addition, the first power supply module 230 applies power to the plurality of first heaters 210a, 210b, 210n. The first heaters 210a, 210b, . . . , 210n may be DC heaters, and the first power supply module 230 apply power to the plurality of first heaters 210a, 210b, . . . , 210n according to the control of the control module 250.

The power may be simultaneously applied to the first heaters 210a, 210b, . . . , 210n and the second heaters 220a, 220b, 220c, and 220d. However, the present exemplary embodiment is not limited thereto. It is also possible that the power is first applied to any one of the first heaters 210a, 210b, . . . , 210n and the second heaters 220a, 220b, 220c, and 220d, and is then applied to the other of the first heaters 210a, 210b, . . . , 210n and the second heaters 220a, 220b, 220c, and 220d.

As described above, the first heaters 210a, 210b, . . . , 210n may be distributed in some regions of the electrostatic chuck 122, and the second heaters 220a, 220b, 220c, and 220d may be distributed in all regions of the electrostatic chuck 122. For example, when the electrostatic chuck 122 is divided into the four regions such as the first region 310, the second region 320, the third region 330, and the fourth region 340, the first heater 210a, 210b, . . . , 210n may be distributed in the third region 330 and the fourth region 340, and the second heaters 220a, 220b, 220c, and 220d may be distributed in the first region 310, the second region 320, the third region 330 and the fourth region 340.

When the substrate W is treated using the plasma, the second heaters 220a, 220b, 220c, and 220d may keep surface temperatures in the respective regions 310, 320, 330, and 340 of the electrostatic chuck 122 constant through the feedback control. However, in order to improve etch rate (ER), critical dimension (CD) distribution, or the like, the first heaters 210a, 210b, . . . , 210n and the second heaters 220a, 220b, 220c, and 220d need to be independently controlled.

When the control module 250 wants to independently control the first heaters 210a, 210b, . . . , 210n and the second heaters 220a, 220b, 220c, and 220d based on the ER, the CD distribution, or the like, the control module 250 controls outputs applied to the second heater 220a, 220b, 220c, and 220d. The control module 250 may control outputs of the second heaters disposed in all regions 310, 320, 330, and 340 of the electrostatic chuck 122 or control outputs of the second heaters disposed in some regions of the electrostatic chuck 122. The control module 250 may control the outputs applied to the second heaters 220a, 220b, 220c, and 220d by controlling offsets of the second heaters 220a, 220b, 220c, and 220d (S520). Temperatures of all regions 310, 320, 330, and 340 of the electrostatic chuck 122 may be changed due to changes in the outputs of the second heaters 220a, 220b, 220c, and 220d (S530).

Then, the control module 250 controls outputs applied to the first heaters 210a, 210b, 210n. The control module 250 may control the outputs applied to the first heaters 210a, 210b, . . . , 210n disposed in the remaining regions other than the sensor regions in the multi-zones (S540), and may compensate for surface temperatures of the electrostatic chuck 122 in the remaining regions by changes in the outputs of the first heaters 210a, 210b, 210n and return the surface temperatures in the remaining regions to a target temperature (S550).

Here, the sensor regions refer to regions in which the surface temperature measurement modules 410a, 410b, 410c, and 410d are distributed. In addition, the remaining regions other than the sensor regions refer to regions in which the first heaters 210a, 210b, . . . , 210n are distributed. The surface temperature measurement modules 410a, 410b, 410c, 410d and the first heaters 210a, 210b, . . . , 210n may be distributed so as not to overlap each other in the height direction (third direction 30) of the electrostatic chuck 122.

Hereinabove, the ESC temperature control unit 200 and the substrate treating apparatus 100 including the same have been described with reference to FIGS. 1 to 9. The ESC temperature control unit 200 according to the present disclosure may operate according to an independent control algorithm by calculating temperature change values versus AC heater sensor offsets, temperature change values versus multi-zone outputs, and the like, based on experimental data. Accordingly, in the present disclosure, independent control of all multi-zone regions including the sensor regions may be enabled, and as described above, the ESC temperature control unit 200 may be used to improve and evaluate the CD distribution.

The ESC temperature control unit 200 may operate in a control manner of adjusting the offsets of the AC heater sensors to change temperatures of all regions and then compensating for temperatures of the remaining regions other than the sensor regions with DC heater sensors of the multi-zones. In this case, multi-zone DC heater outputs in AC heater sensor regions may be fixed without change. In addition, the ESC temperature control unit 200 may obtain an effect of offsetting a temperature crosstalk influence on the sensor regions through the above control manner.

The ESC temperature control unit 200 is for temperature distribution. In the present exemplary embodiment, the first heaters 210a, 210b, . . . , 210n and the second heaters 220a, 220b, 220c, and 220d may be independently controlled based on measurement results of the surface temperature measurement modules 410a, 410b, 410c, and 410d.

Meanwhile, when the substrate W is treated using the plasma, it is possible to measure and control the CD distribution after measuring and controlling temperature distribution using the ESC temperature control unit 200.

Exemplary embodiments of the present disclosure have been described hereinabove with reference to the accompanying drawings, but the present disclosure is not limited to the above-described exemplary embodiments, and may be implemented in various different forms, and one of ordinary skill in the art to which the present disclosure pertains may understand that the present disclosure may be implemented in other specific forms without changing the technical concept or features of the present disclosure. Therefore, it is to be understood that the exemplary embodiments described above are illustrative rather than being restrictive in all aspects.

What is claimed is:

1. A substrate treating apparatus comprising:
a housing;
a substrate support unit disposed within the housing and supporting a substrate using an electrostatic chuck (ESC);
a shower head unit disposed in the housing and supplying a process gas in a direction in which the substrate is positioned;
a plasma generating unit exciting the process gas into a plasma state so that the substrate is treated; and
an ESC temperature control unit provided in the substrate support unit and controlling a temperature of the electrostatic chuck,
wherein the ESC temperature control unit includes:
a plurality of first heaters;
a plurality of second heaters providing power different from that of the first heaters; and
a control module controlling the first heaters and the second heaters, and
the control module independently controls the first heaters and the second heaters.

2. The substrate treating apparatus of claim 1, wherein the control module independently controls the first heaters and the second heaters based on temperature distribution in a plurality of regions of the electrostatic chuck.

3. The substrate treating apparatus of claim 1, wherein the control module controls the first heaters and the second heaters in order of the second heaters and the first heaters.

4. The substrate treating apparatus of claim 1, wherein the control module controls the second heaters based on an offset related to a surface temperature of the electrostatic chuck.

5. The substrate treating apparatus of claim 1, wherein the first heaters and the second heaters are controlled based on temperature distribution and then controlled based on critical dimension (CD) distribution.

6. The substrate treating apparatus of claim 1, wherein the first heaters are heaters operating using direct current (DC), and the second heaters are heaters operating using alternating current (AC).

7. The substrate treating apparatus of claim 1, wherein the first heaters are disposed at a higher level than the second heaters.

8. The substrate treating apparatus of claim 1, wherein the electrostatic chuck is divided into a plurality of regions, an n+1-th region is disposed to surround an n-th region, and n is a natural number.

9. The substrate treating apparatus of claim 8, wherein the first heaters are provided in some of the plurality of regions, and the second heaters are provided in each of the plurality of regions.

10. The substrate treating apparatus of claim 1, wherein the number of first heaters is larger than the number of second heaters.

11. The substrate treating apparatus of claim 1, wherein the first heaters are lower output heaters than the second heaters.

12. The substrate treating apparatus of claim 1, wherein the first heaters are provided in the same number at regular intervals in a plurality of regions of the electrostatic chuck.

13. The substrate treating apparatus of claim 1, wherein the ESC temperature control unit further includes surface temperature measurement modules measuring a surface temperature of the electrostatic chuck.

14. The substrate treating apparatus of claim 13, wherein the control module independently controls the first heaters and the second heaters based on the surface temperature of the electrostatic chuck.

15. The substrate treating apparatus of claim 13, wherein the surface temperature measurement modules are disposed at a higher level than the first heaters and the second heaters.

16. The substrate treating apparatus of claim 13, wherein the surface temperature measurement modules are provided in each of a plurality of regions of the electrostatic chuck.

17. A substrate treating apparatus comprising:
a housing;
a substrate support unit disposed within the housing and supporting a substrate using an electrostatic chuck;
a shower head unit disposed in the housing and supplying a process gas in a direction in which the substrate is positioned;
a plasma generating unit exciting the process gas into a plasma state so that the substrate is treated; and
an ESC temperature control unit provided in the substrate support unit and controlling a temperature of the electrostatic chuck,
wherein the ESC temperature control unit includes:
a plurality of first heaters;
a plurality of second heaters providing power different from that of the first heaters; and
a control module controlling the first heaters and the second heaters,
the control module independently controls the first heaters and the second heaters,
the control module controls the first heaters and the second heaters in order of the second heaters and the first heaters,
the first heaters are heaters operating using DC, and the second heaters are heaters operating using AC,
the first heaters are disposed at a higher level than the second heaters, and
the first heaters are provided in some of a plurality of regions of the electrostatic chuck, and the second heaters are provided in each of the plurality of regions.

18. An ESC temperature control unit controlling a temperature of an electrostatic chuck supporting a substrate when the substrate is treated using plasma, comprising:
a plurality of first heaters;
a plurality of second heaters providing power different from that of the first heaters; and
a control module controlling the first heaters and the second heaters,
wherein the control module independently controls the first heaters and the second heaters.

19. The ESC temperature control unit of claim 18, wherein the control module independently controls the first heaters and the second heaters based on temperature distribution in a plurality of regions of the electrostatic chuck.

20. The ESC temperature control unit of claim 18, wherein the first heaters and the second heaters are controlled based on temperature distribution and then controlled based on CD distribution.
